(19) United States
(12) Patent Application Publication
(10) Pub. No.: US 2026/0219577 A1
(43) Pub. Date: Jul. 30, 2026

(54) RADIATION-SENSITIVE COMPOSITION AND METHOD FOR FORMING RESIST PATTERN

(71) Applicant: JSR CORPORATION, Tokyo (JP)

(72) Inventor: Ken MARUYAMA, Tokyo (JP)

(73) Assignee: JSR CORPORATION, Tokyo (JP)

(21) Appl. No.: 19/576,194

(22) Filed: Mar. 24, 2026

Related U.S. Application Data
(63) Continuation of application No. PCT/JP2024/028429, filed on Aug. 8, 2024.

(30) Foreign Application Priority Data
Sep. 27, 2023 (JP) 2023-166429

(51) Int. Cl. G03F 7/039; C08F 212/14; C08F 220/18; C08F 220/30; G03F 7/004; G03F 7/32

(52) U.S. Cl. CPC G03F 7/0397; C08F 212/24; C08F 220/1807; C08F 220/1809; C08F 220/301; G03F 7/0045; C08F 2800/10; G03F 7/322

(57) ABSTRACT

A radiation-sensitive composition contains: a polymer, solubility of which in a developer solution is capable of being altered by an action of an acid; and a compound having an anion and a radiation-sensitive onium cation. The polymer has a structural unit including a group that generates a sulfonic acid by an action of radiation. The polymer includes an iodo group. At least one of the anion and the radiation-sensitive onium cation includes an acid-labile group.

### CROSS-REFERENCE TO RELATED APPLICATIONS

The present application is a continuation application of International Patent Application No. PCT/JP2024/028429 filed Aug. 8, 2024, which claims priority to Japanese Patent Application No. 2023-166429 filed Sep. 27, 2023. The contents of these applications are incorporated herein by reference in their entirety.

### BACKGROUND OF THE DISCLOSURE

### Technical Field

The present invention relates to a radiation-sensitive composition and a method of forming a resist pattern.

### Discussion of the Background

A radiation-sensitive composition for use in microfabrication by lithography generates an acid at light-exposed regions upon an irradiation with radiation e.g., an electromagnetic wave such as a far ultraviolet ray such as an ArF excimer laser beam (wavelength of 193 nm), a KrF excimer laser beam (wavelength of 248 nm), etc. or an extreme ultraviolet ray (EUV) (wavelength of 13.5 nm), or a charged particle ray such as an electron beam. A chemical reaction in which the acid serves as an origin causes a difference between the light-exposed regions and light-unexposed regions in rates of dissolution in a developer solution, whereby a resist pattern is formed on a substrate.

Such a radiation-sensitive composition is required not only to be favorable in sensitivity to radiation such as extreme ultraviolet rays and electron beams, but also to be superior in CDU (Critical Dimension Uniformity), development defect suppressibility, and the like.

Types, molecular structures, and the like of polymers, acid generating agents, and other components which may be used in radiation-sensitive compositions have been investigated to meet these requirements, and combinations thereof have been further investigated in detail (see, Japanese Unexamined Patent Application, Publication No. 2010-134279, Japanese Unexamined Patent Application, Publication No. 2014-224984, Japanese Unexamined Patent Application, Publication No. 2016-047815, and Japanese Unexamined Patent Application, Publication No. 2021-009357).

### SUMMARY OF THE INVENTION

According to one aspect of the invention, a radiation-sensitive composition contains: a polymer, solubility of which in a developer solution is capable of being altered by an action of an acid; and a compound having an anion and a radiation-sensitive onium cation, wherein the polymer has a structural unit including a group that generates a sulfonic acid by an action of radiation, the polymer includes an iodo group, and at least one of the anion and the radiation-sensitive onium cation includes an acid-labile group.

According to another aspect of the present invention, a method of forming a resist pattern includes: applying the above-described radiation-sensitive composition directly or indirectly on a substrate; exposing a resist film formed by the applying; and developing the resist film exposed.

The radiation-sensitive composition according to the one aspect of the present invention is superior in sensitivity, CDU. and development defect suppressibility. The method of forming a resist pattern of the present invention enables a resist pattern that is superior in CDU and development defect suppressibility to be formed with favorable sensitivity.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range.

Along with further microfabrication of resist patterns, required levels for the above-described performance are further elevated, and thus a radiation-sensitive composition that satisfies these requirements are demanded.

An object of the present invention is to provide: a radiation-sensitive composition that is superior in sensitivity, CDU, and development defect suppressibility, and a method of forming a resist pattern performed using the radiation-sensitive composition.

The radiation-sensitive composition and the method of forming a resist pattern of the present invention are described in detail below.

### Radiation-Sensitive Composition

The radiation-sensitive composition contains a polymer (hereinafter, may be also referred to as “(A) polymer” or “polymer (A)”), solubility of which in a developer solution is capable of being altered by an action of an acid; and a compound (hereinafter, may be also referred to as “(Z) compound” or “compound (Z)”) having an anion and a radiation-sensitive onium cation.

Due to containing the polymer (A) and the compound (Z), and fulfilling the following requirements (i) to (iii) which will be described later in detail, the radiation-sensitive composition is superior in sensitivity, CDU, and development defect suppressibility.
Requirement (i): The polymer (A) has a structural unit including a group that generates a sulfonic acid by an action of radiation.
Requirement (ii): The polymer (A) includes an iodo group.
Requirement (iii): At least one of the anion and the radiation-sensitive onium cation in the compound (Z) includes acid-labile group.

Although not necessarily clarified and without wishing to be bound by any theory, the reason for superior sensitivity, CDU, and development defect suppressibility of the radiation-sensitive composition, due to containing the polymer (A) and the compound (Z), and fulfilling the requirements (i) to (iii) may be presumed, for example, as in the following, for example. It is considered that by fulfilling the requirement (i), diffusion of the sulfonic acid generated upon exposure can be controlled, whereby the radiation-sensitive composition may exhibit superior CDU. It is considered that by fulfilling the requirement (ii), the absorption efficiency of radiation can improve, whereby the radiation-sensitive composition may exhibit superior sensitivity and CDU. By fulfilling the requirement (iii), the solubility in a developer solution can improve, whereby the radiation-sensitive composition may exhibit superior development defect suppressibility. Therefore, fulfilling requirements (i) to (iii) is considered to enable a balance among sensitivity, CDU, and development-defect suppressibility to be favorably achieved.

The radiation-sensitive composition enables the sensitivity and CDU to be more improved by further fulfilling the following requirement (iv).
Requirement (iv): At least one of the anion and the radiation-sensitive onium cation in the compound (Z) further includes an iodo group.

The radiation-sensitive composition typically contains an organic solvent (hereinafter, may be also referred to as “(D) organic solvent” or “organic solvent (D)”). The radiation-sensitive composition may also contain a radiation-sensitive acid generating agent or an acid diffusion control agent, other than the compound (Z). The radiation-sensitive composition may also contain a polymer (hereinafter, may be also referred to as “(F) polymer” or “polymer (F)”) having a percentage content of fluorine atoms greater than that of the polymer (A). The radiation-sensitive composition may contain, within a range not leading to impairment of the effects of the present invention, other optional component(s).

The radiation-sensitive composition can be prepared by, for example: mixing the polymer (A) and the compound (Z), and as needed, a radiation-sensitive acid generating agent, an acid diffusion control agent, the organic solvent (D), the polymer (F), other optional component(s), and the like in a predefined proportion; and filtering a thus obtained mixture through a membrane filter having a pore size of no greater than 0.2 μm.

Each component contained in the radiation-sensitive composition is described below.

### (A) Polymer

The polymer (A) is a polymer, solubility of which in a developer solution is capable of being altered by an action of an acid. The polymer (A) has a structural unit (a) (hereinafter, may be also merely referred to as “structural unit (a)”) including a group that generates a sulfonic acid by an action of radiation. The “polymer” as referred to herein means a compound having a structure in which one type, or two or more types of monomers are repeatedly bonded. The “structural unit” as referred to herein means a partial structure derived from one molecule of monomer, among structures constituting the polymer main chain. The radiation-sensitive composition can contain one type, or two or more types of the polymer (A).

The polymer (A) preferably has a structural unit (b) (hereinafter, may be also merely referred to as “structural unit (b)”) which includes an acid-labile group. The polymer (A) preferably has a structural unit (c) (hereinafter, may be also merely referred to as “structural unit (c)”) which includes a phenolic hydroxyl group. The polymer (A) may further have an other structural unit (hereinafter, may be also merely referred to as “structural unit (d)”) aside from the structural unit (a), the structural unit (b), and the structural unit (c).

The polymer (A) has an iodo group (requirement (ii)). Due to the polymer (A) having an iodo group, absorption efficiency of radiation improves, thereby leading to the radiation-sensitive composition that may exhibit superior sensitivity and CDU. The polymer (A) may have the iodo group in its main chain, or in a side chain. The “main chain” as referred to herein means the longest atom chain among atom chains that constitute the polymer. The “side chain” as referred to herein means atom chains other than the main chain, among the atom chains constituting the polymer. The polymer (A) preferably has an iodo group in the side chain, and it is more preferred that the structural unit included in the polymer (A) has an iodo group. The iodo group may be included in any one of the structural unit (a) to the structural unit (d) described above. In light of enabling the absorption efficiency of radiation to be more improved, the iodo group preferably bonds to the aromatic ring.

The number of iodo groups in the polymer (A) may be one or more, and is preferably five or more. The number of the iodo groups being 15 or more is more preferred, because sensitivity of the radiation-sensitive composition is more improved. The number of the iodo groups being 30 or more is still more preferred, because the sensitivity and CDU of the radiation-sensitive composition are furthermore improved. The number of the iodo groups being 40 or more is particularly preferred because the sensitivity and CDU of the radiation-sensitive composition are even further improved. The number of the iodo groups in the polymer (A) as referred to herein is defined as the value obtained by multiplying the number of the iodo groups in one structural unit by the proportion (mol %) of the structural unit contained in the polymer (A).

The lower limit of a proportion of the polymer (A) contained in the radiation-sensitive composition is, with respect to total components other than the organic solvent (D) contained in the radiation-sensitive composition, preferably 50% by mass, more preferably 70% by mass, and still more preferably 80% by mass. The upper limit of the proportion is preferably 99% by mass, and more preferably 95% by mass.

The lower limit of a polystyrene equivalent weight average molecular weight (Mw) of the polymer (A) as determined by gel permeation chromatography (GPC) is preferably 1,000, more preferably 2,000, still more preferably 3,000, and even further preferably 5,000. The upper limit of the Mw is preferably 30,000, more preferably 20,000, and still more preferably 10,000. When the Mw of the polymer (A) falls within the above range, coating characteristics of the radiation-sensitive composition can be improved. The Mw of the polymer (A) can be adjusted by regulating, for example, a type and/or a using amount, etc., of a polymerization initiator to be used in synthesis of the polymer (A).

The upper limit of a ratio (hereinafter, may be also referred to as “Mw/Mn”) of Mw to a polystyrene-equivalent number average molecular weight (Mn) of the polymer (A) as determined by GPC is preferably 2.5, more preferably 2.0, and still more preferably 1.8. The lower limit of the ratio is typically 1.0, preferably 1.1, more preferably 1.2, and still more preferably 1.3.

### Methods of Measuring Mw and Mn

As referred to herein, Mw and Mn of the polymer are values measured by using gel permeation chromatography (GPC) under the following conditions.
GPC columns: “G2000 HXL”×2, “G3000 HXL”×1, and “G4000 HXL”×1, available from Tosoh Corporation
column temperature: 40° C.
elution solvent: tetrahydrofuran
flow rate: 1.0 mL/min
sample concentration: 1.0% by mass
amount of injected sample: 100 μL
detector: differential refractometer
standard substance: mono-dispersed polystyrene

The polymer (A) can be synthesized by, for example, polymerizing a monomer that gives each structural unit by a well-known method.

Each structural unit included in the polymer (A) is described below.

### Structural Unit (a)

The structural unit (a) structural unit including a group (hereinafter, may be also referred to as “radiation-sensitive sulfonic acid-generating group”) that generates a sulfonic acid by an action of radiation (requirement (i)). Due to the polymer (A) having the structural unit (a), diffusion of the sulfonic acid generated upon exposure may be controlled, thereby leasing to superior CDU of the radiation-sensitive composition. The polymer (A) can have one type, or two or more types of the structural unit (a).

The radiation-sensitive sulfonic acid-generating group is exemplified by a group which includes a sulfonic acid anion and a radiation-sensitive onium cation. Such radiation-sensitive sulfonic acid-generating groups are classified into: a structure (hereinafter, may be also referred to as “structure (1)”) in which a sulfonic acid anion is bonded to the side chain of the polymer; and a structure (hereinafter, may be also referred to as “structure (2)”) in which a radiation-sensitive onium cation is bonded to the side chain of the polymer. As the structural unit (a), the structure (1) is preferred. The case of being the structure (1) is preferred since diffusion of the sulfonic acid generated upon exposure may be more controlled, thereby resulting in more improved CDU.

Due to the radiation-sensitive sulfonic acid-generating group, the polymer (A) exerts a function as a radiation-sensitive acid generating agent in the radiation-sensitive composition, i.e., the sulfonic acid generated by the action of radiation allows for dissociation of an acid-labile group contained in the structural unit (b) or the compound (Z) described later. For example, the structural unit (a) generates a sulfonic acid by an action of radiation, and this sulfonic acid allows for dissociation of the acid-labile group described later.

In the case in which the radiation-sensitive sulfonic acid-generating group corresponds to the structure (1) described above, the structural unit (a) is exemplified by a structural unit represented by the following formula (a).

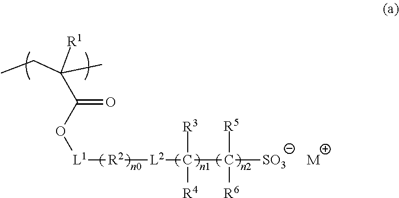

In the above formula (a): R¹ represents a hydrogen atom, a fluorine atom, a methyl group, or a trifluoromethyl group; L¹ and L² each independently represent a single bond or a divalent linking group; R² represents a group obtained by removing two hydrogen atoms from a substituted or unsubstituted ring structure having 5 or more ring atoms; n₀ is 0 or 1; R³ and R⁴ each independently represent a hydrogen atom, a fluorine atom, an alkyl group having 1 to 10 carbon atoms, or a monovalent fluorinated alkyl group having 1 to 10 carbon atoms; n₁ is an integer of 0 to 10; R⁵ and R⁶ each independently represent a fluorine atom or a monovalent fluorinated alkyl group having 1 to 10 carbon atoms; n₂ is an integer of 1 to 10; and M⁺ represents a monovalent radiation-sensitive onium cation.

R¹ represents preferably a hydrogen atom or a methyl group.

The “linking group” as referred to herein means a group that links two or more structures. The linking group remains in the structure of a compound or a polymer due to a reason such as a synthesis material or a synthesis procedure, and does not influence the effects of the present invention or has an extremely small influence on the effects of the present invention. It is to be noted that contribution of all the structures other than the linking group to the exhibition of the effects of the present invention is not intended hereby.

The divalent linking group which may be represented by L¹ and L² is not particularly limited as long as it is a group that links two structures to which L¹ and L² bond, respectively, and examples thereof include a carbonyl group, an ether group, a carbonyloxy group, a sulfide group, a sulfonyl group, an alkanediyl group having 1 to 10 carbon atoms, or a group obtained by combining the same.

Examples of the ring structure having no less than 5 ring atoms that gives R² include an aliphatic hydrocarbon ring having no less than 5 ring atoms, an aliphatic heterocyclic ring having no less than 5 ring atoms, an aromatic hydrocarbon ring having no less than 6 ring atoms, and an aromatic heterocyclic ring having no less than 5 ring atoms.

The number of “ring atoms” as referred to herein means the number of atoms constituting a ring structure, and in the case of a polycyclic ring, the number of “ring atoms” means the number of atoms constituting the polycyclic ring. The “polycyclic ring” encompasses not only a spiro-type polycyclic ring in which two rings have one shared atom and a condensed polycyclic ring in which two rings have two shared atoms, but also a ring-assembled polycyclic ring in which two rings are connected by a single bond without having any shared atom

The “ring structure” encompasses both an “alicyclic ring” and an “aromatic ring”. The “alicyclic ring” encompasses both an “aliphatic hydrocarbon ring” and an “aliphatic heterocyclic ring”. Of the alicyclic rings, a polycyclic one containing both the aliphatic hydrocarbon ring and the aliphatic heterocyclic ring falls under the “aliphatic heterocyclic ring”. The “aromatic ring” encompasses an “aromatic hydrocarbon ring” and an “aromatic heterocyclic ring”. Of the aromatic rings, a polycyclic one containing both the aromatic hydrocarbon ring and the aromatic heterocyclic ring falls under the “aromatic heterocyclic ring”.

Examples of the aliphatic hydrocarbon ring having no less than 5 ring atoms include: monocyclic saturated alicyclic rings such as a cyclopentane ring, a cyclohexane ring, a cycloheptane ring, a cyclooctane ring, a cyclononane ring, a cyclodecane ring, and a cyclododecane ring; monocyclic unsaturated alicyclic rings such as a cyclopentene ring, a cyclohexene ring, a cycloheptene ring, a cyclooctene ring, and a cyclodecene ring; polycyclic saturated alicyclic rings such as a norbornane ring, an adamantane ring, a tricyclodecane ring, a tetracyclododecane ring, and a steroid structure; and polycyclic unsaturated alicyclic rings such as a norbornene ring and a tricyclodecene ring. The “steroid structure” as referred to herein means a structure having, as a basic skeleton, a skeleton (sterane skeleton) obtained by condensation of three 6-membered rings and one 5-membered ring.

Examples of the aliphatic heterocyclic ring having no less than 5 ring atoms include: lactone rings such as a hexanolactone ring and a norbornanelactone ring; sultone rings such as a hexanosultone ring and a norbornane sultone ring; oxygen atom-containing heterocyclic rings such as a dioxolane ring, an oxacycloheptane ring, and an oxanorbornane ring; nitrogen atom-containing heterocyclic rings such as an azacyclohexane ring and a diazabicyclooctane ring; and sulfur atom-containing heterocyclic rings such as a thiacyclohexane ring and a thianorbornane ring.

Examples of the aromatic hydrocarbon ring having no less than 6 ring atoms include: a benzene ring; condensed polycyclic aromatic hydrocarbon rings such as a naphthalene ring, an anthracene ring, a fluorene ring, a biphenylene ring, a phenanthrene ring, and a pyrene ring; ring-assembled aromatic hydrocarbon rings such as a biphenyl ring, a terphenyl ring, a binaphthalene ring, and a phenylnaphthalene ring; a 9,10-ethanoanthracene ring; and a triptycene ring.

Examples of the aromatic heterocyclic ring having no less than 5 ring atoms include: oxygen atom-containing heterocyclic rings such as a furan ring, a pyran ring, a benzofuran ring, and a benzopyran ring; nitrogen atom-containing heterocyclic rings such as a pyridine ring, a pyrimidine ring, and an indole ring; and sulfur atom-containing heterocyclic rings such as a thiophene ring.

The ring structure is preferably an aliphatic hydrocarbon ring or an aromatic hydrocarbon ring, and more preferably a polycyclic saturated alicyclic ring, a benzene ring, or a condensed polycyclic aromatic hydrocarbon ring.

The lower limit of the number of ring atoms of the ring structure is preferably 6, more preferably 8, still more preferably 9, and particularly preferably 10. The upper limit of the number of ring atoms is preferably 25.

In the ring structure, a part or all of hydrogen atoms bonding to atoms constituting the ring structure may be substituted with a substituent. Examples of the substituent include halogeno groups such as a fluoro group and an iodo group, a hydroxy group, a carboxy group, a cyano group, a nitro group, an alkyl group, a fluorinated alkyl group, an alkoxy group, an alkoxycarbonyl group, an alkoxycarbonyloxy group, an acyl group, and an acyloxy group.

In the case in which the ring structure has an iodo group as a substituent, the requirement (ii) described above is satisfied.

It is preferred that n₀ is 1.

Examples of the alkyl group having 1 to 10 carbon atoms which may be represented by R³ and R⁴ include a methyl group, an ethyl group, and a propyl group.

The “number of carbon atoms” as referred to herein means the number of carbon atoms constituting a group. The “fluorinated alkyl group” means a group obtained by substituting a fluorine atom for a part or all of hydrogen atoms included in an alkyl group.

Examples of the fluorinated alkyl group having 1 to 10 carbon atoms which may be represented by R³, R⁴, R⁵, and R⁶ include perfluoroalkyl groups such as a trifluoromethyl group.

R³ and R⁴ each represent preferably a hydrogen atom or a fluorinated alkyl group, more preferably a hydrogen atom or a perfluoroalkyl group, and still more preferably a hydrogen atom or a trifluoromethyl group.

It is preferred that R⁵ and R⁶ each represent a fluorine atom.

n₁ is preferably 0 to 5, more preferably 0 to 2, and still more preferably 0 or 1.

n₂ is preferably 1 to 5, more preferably 1 to 3, and still more preferably 1.

The monovalent radiation-sensitive onium cation represented by M⁺ is not particularly limited as long as it is known as a radiation-sensitive onium cation in an onium salt used as a radiation-sensitive acid generating agent to be contained in a radiation-sensitive composition. Examples thereof include a sulfonium cation (S⁺) and an iodonium cation (I⁺).

The monovalent radiation-sensitive onium cation represented by M⁺ is exemplified by a monovalent cation represented by the following formula (r-a).

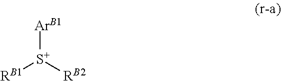

In the above formula (r-a): Ar^{B1} represents a group obtained by removing one hydrogen atom from a substituted or unsubstituted aromatic hydrocarbon ring; and R^{B1} and R^{B2} each independently represent a group obtained by removing one hydrogen atom from a substituted or unsubstituted aromatic hydrocarbon ring, or R^{B1} and R^{B2} taken together represent a substituted or unsubstituted polycyclic sulfur atom-containing aromatic heterocyclic ring together with the sulfur atom to which R^{B1} and R^{B2} bond.

Examples of the aromatic hydrocarbon ring which may be represented by Ar^{B1}, R^{B1}, or R^{B2} include those similar to the aromatic hydrocarbon rings exemplified for R² in the above formula (a). The aromatic hydrocarbon ring which may be represented by Ar^{B1}, R^{B1}, or R^{B2} is preferably a benzene ring.

Examples of the polycyclic sulfur atom-containing aromatic heterocyclic ring represented by R^{B1} and R^{B2} taken together, together with the sulfur atom to which R^{B1} and R^{B2} bond, include a dibenzothiophene ring.

In the aromatic hydrocarbon ring and the polycyclic sulfur atom-containing aromatic heterocyclic ring, at least one hydrogen atom may be substituted with a substituent. Examples of the substituent include those similar to the substituents that the ring structure in R² of the above formula (a) may have. The substituent is preferably an iodo group, a fluorinated alkyl group, or a fluoro group.

In the case in which the aromatic hydrocarbon ring or the polycyclic sulfur atom-containing aromatic heterocyclic ring has an iodo group as a substituent, the requirement (ii) described above is satisfied.

In the case in which the aromatic hydrocarbon ring or the polycyclic sulfur atom-containing aromatic heterocyclic ring has a fluoro group as a substituent, the sensitivity of the radiation-sensitive composition can be more improved.

Examples of the structural unit (a) include structural units represented by the following formulae (a-1) to (a-4).

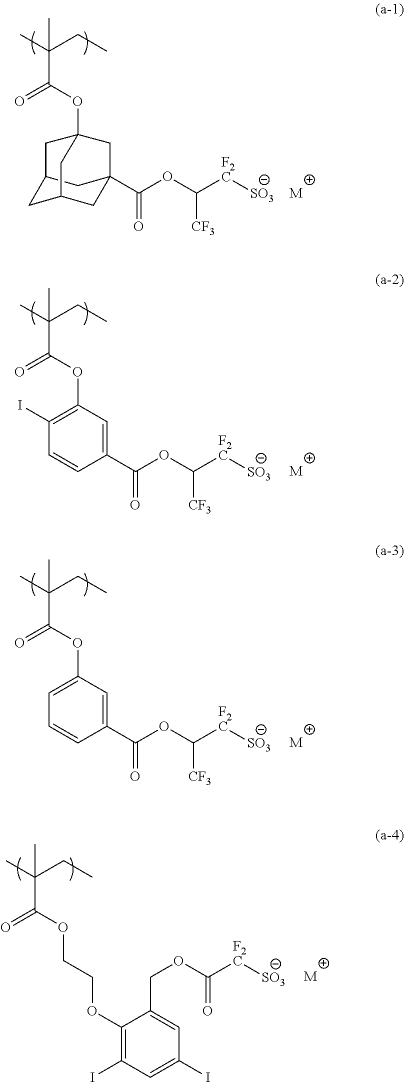

In the above formulae (a-1) to (a-4), M⁺ is as defined in the above formula (a).

The lower limit of a proportion of the structural unit (a) in the polymer (A) with respect to the total structural units constituting the polymer (A) is preferably 1 mol %, more preferably 3 mol %, still more preferably 5 mol %, and particularly preferably 7 mol %. The upper limit of the proportion is preferably 40 mol %, more preferably 30 mol %, still more preferably 20 mol %, and particularly preferably 15 mol %.

### Structural Unit (b)

The structural unit (b) is a structural unit which includes an acid-labile group. The “acid-labile group” as referred to herein means a group that substitutes for a hydrogen atom in a carboxy group or a hydroxy group and is capable of being dissociated by an action of an acid to give a carboxy group or a hydroxy group.

When the polymer (A) has the structural unit (b), the acid-labile group is dissociated from the structural unit (b) by an action of the acid generated from the polymer [A] or the like due to the action of radiation, whereby a difference is generated in the solubility of the polymer (A) in a developer solution between light-exposed regions and light-unexposed regions, and thus a resist pattern can be formed.

The acid-labile group is a group that substitutes for a hydrogen atom included in a carboxy group or a hydroxy group in the structural unit (b). In other words, in the structural unit (b), the acid-labile group is bonded to an ethereal oxygen atom of a carbonyloxy group.

Examples of the acid-labile group include groups represented by the following formulae (s-1) to (s-3).

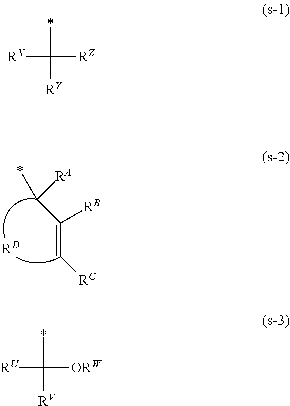

In the above formulae (s-1) to (s-3), * denotes a binding site to the ethereal oxygen atom of the carboxy group or the oxygen atom of the hydroxy group.

In the above formula (s-1): R^{X} represents a substituted or unsubstituted monovalent hydrocarbon group having 1 to 20 carbon atoms; and R^{Y} and R^{Z} each independently represent a monovalent hydrocarbon group having 1 to 20 carbon atoms, or R^{Y} and R^{Z} taken together represent a saturated alicyclic ring having 3 to 20 ring atoms, together with the carbon atom to which R^{Y} and R^{Z} bond.

In the above formula (s-2): R^{A} represents a hydrogen atom; R^{B} and R^{C} each independently represent a hydrogen atom or a monovalent hydrocarbon group having 1 to 20 carbon atoms; and R^{D} represents a divalent hydrocarbon group having 1 to 20 carbon atoms, which represents an unsaturated alicyclic ring having 4 to 20 ring atoms, together with the three carbon atoms to which R^{A}, R^{B} and R^{C} bond, respectively.

In the above formula (s-3): R^{U} and R^{V} each independently represent a hydrogen atom or a monovalent hydrocarbon group having 1 to 20 carbon atoms, and R^{W} represents a monovalent hydrocarbon group having 1 to 20 carbon atoms; or R^{U} and R^{V} taken together represent a saturated alicyclic ring having 3 to 20 ring atoms, together with the carbon atom to which R^{U} and R^{V} bond, and R^{W} represents a monovalent hydrocarbon group having 1 to 20 carbon atoms; or R^{V} and R^{W} taken together represent an oxygen atom-containing aliphatic heterocyclic ring having 4 to 20 ring atoms, together with the carbon atom to which R^{V} bonds and the oxygen atom to which R^{W} bonds, and R^{U} represents a hydrogen atom or a monovalent hydrocarbon group having 1 to 20 carbon atoms.

The “hydrocarbon group” may encompass an “aliphatic hydrocarbon group” and an “aromatic hydrocarbon group”. The “aliphatic hydrocarbon group” may encompass a “chain hydrocarbon group” and an “alicyclic hydrocarbon group”. From another viewpoint, the “aliphatic hydrocarbon group” may encompass a “saturated hydrocarbon group” and an “unsaturated hydrocarbon group”. The “chain hydrocarbon group” as referred to herein means a hydrocarbon group not having a ring structure but being constituted with only a chain structure, and may be exemplified by both a linear hydrocarbon group and a branched hydrocarbon group. The “alicyclic hydrocarbon group” as referred to herein means a hydrocarbon group having, as a ring structure, not an aromatic ring but an alicyclic ring alone, and may be exemplified by both a monocyclic alicyclic hydrocarbon group and a polycyclic alicyclic hydrocarbon group. With regard to this, it is not necessary for the alicyclic hydrocarbon group to be constituted with only an alicyclic ring; it may have a chain structure in a part thereof. The “aromatic hydrocarbon group” as referred to herein means a hydrocarbon group that includes an aromatic ring as a ring structure. With regard to this, it is not necessary for the aromatic hydrocarbon group to be constituted with only an aromatic ring, and it may have a chain structure or an alicyclic ring in a part thereof.

The monovalent hydrocarbon group having 1 to 20 carbon atoms that gives R^{X}, R^{Y}, R^{Z}, R^{B}, R^{C}, R^{U}, R^{V}, or R^{W} is exemplified by a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

The substituent which may be incorporated in the hydrocarbon group represented by R^{X} is exemplified by those similar to the substituents which may be incorporated in the ring structure in R² of the above formula (a). The case in which R^{X} has an iodo group as a substituent is preferred because the CDU of the radiation-sensitive composition tends to be able to be more improved. Moreover, in this case, the requirement (ii) described above is satisfied.

Examples of the monovalent chain hydrocarbon group having 1 to 20 carbon atoms include: alkyl groups such as a methyl group, an ethyl group, an n-propyl group, an i-propyl group, an n-butyl group, a sec-butyl group, an isobutyl group, and a tert-butyl group; alkenyl groups such as an ethenyl group, a propenyl group, a butenyl group, and a 2-methylprop-1-en-1-yl group; and alkynyl groups such as an ethynyl group, a propynyl group, and a butynyl group.

Examples of the monovalent alicyclic hydrocarbon group having 3 to 20 carbon atoms include: monocyclic alicyclic saturated hydrocarbon groups such as a cyclopentyl group and a cyclohexyl group; polycyclic alicyclic saturated hydrocarbon groups such as a norbornyl group, an adamantyl group, a tricyclodecyl group, and a tetracyclododecyl group; monocyclic alicyclic unsaturated hydrocarbon groups such as a cyclopentenyl group and a cyclohexenyl group; and polycyclic alicyclic unsaturated hydrocarbon groups such as a norbornenyl group, a tricyclodecenyl group, and a tetracyclododecenyl group.

Examples of the monovalent aromatic hydrocarbon group having 6 to 20 carbon atoms include: aryl groups such as a phenyl group, a tolyl group, a xylyl group, a naphthyl group, and an anthryl group; and aralkyl groups such as a benzyl group, a phenethyl group, a naphthylmethyl group, and an anthrylmethyl group.

Examples of the saturated alicyclic ring having 3 to 20 ring atoms which may be represented by R^{Y} and R^{Z} taken together, together with the carbon atom to which R^{Y} and R^{Z} bond, and examples of the saturated alicyclic ring having 3 to 20 ring atoms which may be represented by R^{U} and R^{V} taken together, together with the carbon atom to which R^{U} and R^{V} bond include: monocyclic saturated alicyclic rings such as a cyclopropane ring, a cyclobutane ring, a cyclopentane ring, and a cyclohexane ring; and polycyclic saturated alicyclic rings such as a norbornane ring, an adamantane ring, a tricyclodecane ring, and a tetracyclododecane ring.

The divalent hydrocarbon group having 1 to 20 carbon atoms represented by R^{D} is exemplified by a group obtained by removing one hydrogen atom from a group exemplified as the above-described monovalent hydrocarbon group having 1 to 20 carbon atoms.

Examples of the unsaturated alicyclic ring having 4 to 20 ring atoms represented by R^{D} together with the three carbon atoms to which R^{A}, R^{B}, and R^{C} bond, respectively, include monocyclic unsaturated alicyclic structures such as a cyclobutene structure, a cyclopentene structure, and a cyclohexene structure; and polycyclic unsaturated alicyclic structures such as a norbornene structure; and the like.

Examples of the oxygen atom-containing aliphatic heterocyclic ring having 4 to 20 ring atoms represented by R^{Y} and R^{W} taken together, together with the carbon atom to which R^{V} bonds and the oxygen atom to which R^{W} bonds include an oxacyclobutane ring, an oxacyclopentane ring, an oxacyclohexane ring, an oxacyclobutene ring, an oxacyclopentene ring, and an oxacyclohexene ring, and the like.

In the case in which the R^{Y} and R^{Z} represent a monovalent hydrocarbon group having 1 to 20 carbon atoms, R^{Y} and R^{Z} each represent preferably a chain hydrocarbon group, more preferably an alkyl group, and still more preferably a methyl group. In this case, R^{X} represents preferably a substituted or unsubstituted aromatic hydrocarbon group, more preferably a substituted or unsubstituted aryl group, and still more preferably a phenyl group or an iodophenyl group. A case in which R^{X} represents an aryl group substituted with an iodo group is preferred because the CDU of the radiation-sensitive composition tends to be able to be more improved.

In the case in which R^{Y} and R^{Z} taken together represent a saturated alicyclic ring having 3 to 20 ring atoms together with the carbon atom to which R^{Y} and R^{Z} bond, the saturated alicyclic ring is preferably a cyclopentane ring, a cyclohexane ring, or an adamantane ring. In this case, R^{X} represents preferably a substituted or unsubstituted chain hydrocarbon group, or a substituted or unsubstituted aromatic hydrocarbon group, more preferably an unsubstituted alkyl group, or a substituted or unsubstituted aryl group, and still more preferably a methyl group, an ethyl group, a phenyl group, or an iodophenyl group. A case in which R^{X} represents an aryl group substituted with an iodo group is preferred because the CDU of the radiation-sensitive composition tends to be able to be more improved.

Examples of the acid-labile group include groups represented by the following formulae (s-1-1) to (s-1-8) and (s-3-1) to (s-3-4).

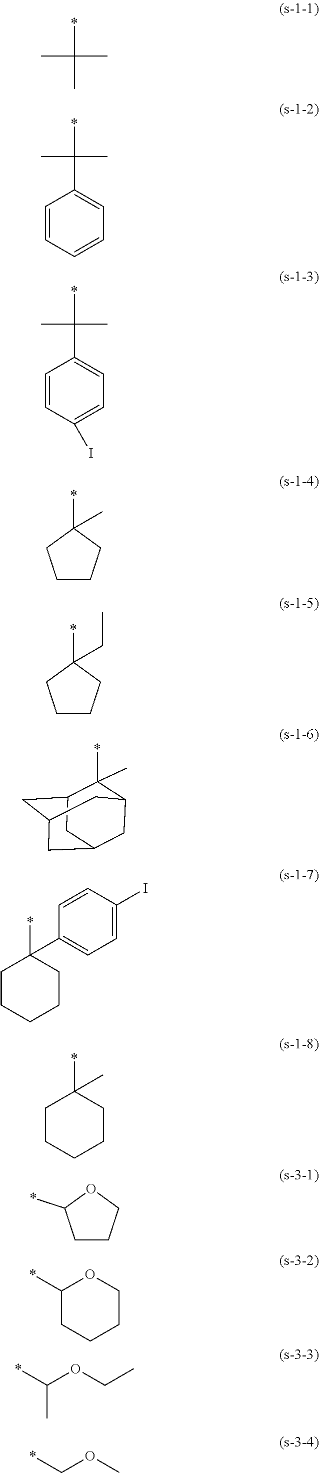

In the above formulae (s-1-1) to (s-1-8) and (s-3-1) to (s-3-4), * is as defined in the above formulae (s-1) and (s-3).

The structural unit (b) is exemplified by a structural unit represented by the following formula (b).

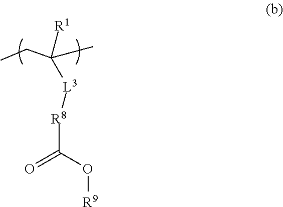

In the above formula (b): R⁷ represents a hydrogen atom, a fluorine atom, a methyl group, or a trifluoromethyl group; L³ represents a single bond, —COO—, or CONH—; R⁸ represents a single bond, or a group obtained by removing two hydrogen atoms from a substituted or unsubstituted aromatic hydrocarbon ring; and R⁹ represents an acid-labile group.

R⁷ represents preferably a hydrogen atom or a methyl group, in light of copolymerizability of a monomer that gives the structural unit (b).

L³ represents preferably a single bond.

The aromatic hydrocarbon ring that gives R⁸ is exemplified by those exemplified as the aromatic hydrocarbon rings among the ring structures in R² of the above formula (a-1). The same applies to the substituent. The aromatic hydrocarbon ring that gives R⁸ is preferably a benzene ring.

In the case in which the polymer (A) has the structural unit (b), the lower limit of a proportion of the structural unit (b) contained in the polymer (A), with respect to the total structural units constituting the polymer (A), is preferably 20 mol %, more preferably 30 mol %, still more preferably 35 mol %, and particularly preferably 40 mol %. The upper limit of the proportion is preferably 80 mol %, more preferably 70 mol %, still more preferably 60 mol %, and particularly preferably 55 mol %.

### Structural Unit (c)

The structural unit (c) is a structural unit which includes a phenolic hydroxyl group.

The “phenolic hydroxyl group” as referred to herein means not only a hydroxy group directly linking to a benzene ring, but any hydroxy group(s) directly linking to an aromatic ring.

In the case of KrF exposure, EUV exposure, or electron beam exposure, the sensitivity of the radiation-sensitive composition can be more enhanced due to the polymer (A) having the structural unit (c). Therefore, in the case in which the polymer (A) has the structural unit (c), the radiation-sensitive composition can be suitably used as a radiation-sensitive composition for KrF exposure, EUV exposure, or electron beam exposure.

The structural unit (c) is exemplified by a structural unit represented by the following formula (c).

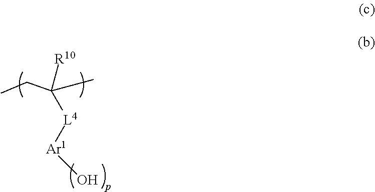

In the above formula (c): R¹⁰ represents a hydrogen atom, a fluorine atom, a methyl group, or a trifluoromethyl group; L⁴ represents a single bond, —COO—, —O— or CONH—; Ar¹ represents a group obtained by removing (p+1) hydrogen atoms from a substituted or unsubstituted aromatic hydrocarbon ring; and p is an integer of 1 to 3.

L⁴ represents preferably a single bond or COO—. It is to be noted that in the case in which L⁴ represents —COO—, with respect to a direction of bonding of this group, —COO—* is preferred, wherein * denotes a binding site to Ar¹.

The aromatic hydrocarbon ring that gives Ar¹ is exemplified by those exemplified as the aromatic hydrocarbon rings among the ring structures in R² of the above formula (a-1). The same applies to the substituent. The aromatic hydrocarbon ring that gives Ar¹ is preferably a benzene ring or a naphthalene ring.

The case in which the aromatic hydrocarbon ring that gives Ar² has an iodo group as a substituent is preferred because the sensitivity of the radiation-sensitive composition tends to be able to be more improved. Furthermore, in this case, the requirement (ii) described above is satisfied.

It is preferred that p is 1 or 2.

Examples of the structural unit (c) include structural units represented by the following formulae (c-1) to (c-3).

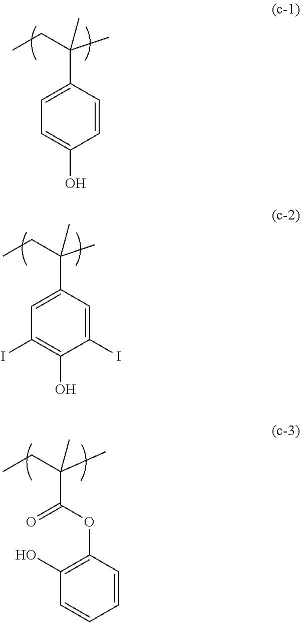

In the case in which the polymer (A) has the structural unit (c), the lower limit of a proportion of the structural unit (c) contained in the polymer (A), with respect to the total structural units constituting the polymer (A), is preferably 20 mol %, more preferably 30 mol %, and still more preferably 35 mol %. The upper limit of the proportion is preferably 70 mol %, more preferably 60 mol %, and still more preferably 50 mol %.

### Structural Unit (d)

The structural unit (d) is an other structural unit aside from the structural unit (a), the structural unit (b), and the structural unit (c). The structural unit (d) is exemplified by: a structural unit which includes a lactone structure, a cyclic carbonate structure, a sultone structure, or a combination thereof; a structural unit which includes an alcoholic hydroxyl group; and a structural unit derived from a vinylaromatic compound.

Examples of the structural unit (d) include structural units represented by the following formulae (d-1) or (d-2).

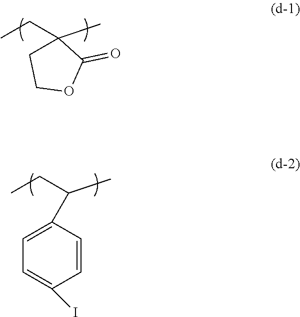

In the case in which the polymer (A) has the structural unit (d), the lower limit of a proportion of the structural unit (d), with respect to the total structural units constituting the polymer (A), is preferably 1 mol %, and more preferably 5 mol %. The upper limit of the proportion is preferably 20 mol %, and more preferably 15 mol %.

### (Z) Compound

The compound (Z) is a compound having an anion (hereinafter, may be also referred to as “anion (X)”) and a radiation-sensitive onium cation (hereinafter, may be also referred to as “cation (Y)”).

The compound (Z) has, depending on the type of the anion group included in the anion (X): a function of generating an acid by an action of radiation in the radiation-sensitive composition; or a function of controlling a diffusion phenomenon of an acid that occurs in a resist film by an action of radiation, thereby inhibiting an unwanted chemical reaction (for example, a dissociation reaction of the acid-labile group) in light-unexposed regions. In other words, in the radiation-sensitive composition, the compound (Z) serves as a radiation-sensitive acid generating agent (hereinafter, may be also referred to as “acid generating agent (B)”) or an acid diffusion control agent (quencher) (hereinafter, may be also referred to as “acid diffusion control agent (C)”), depending on the type of the anion group.

In the case in which the compound (Z) serves as the acid generating agent (B), the acid-labile group incorporated in the structural unit (b) and/or the like included in the polymer (A) is dissociated due to the acid generated from the compound (Z) by an action of radiation, whereby an acidic group such as a carboxy group is produced to cause a difference in solubility of the resist film into a developer solution, between light-exposed regions and light-unexposed regions, thereby enabling a resist pattern to be formed.

In the case in which the compound (Z) serves as the acid diffusion control agent (C), the acid is generated in light-exposed regions to enhance the solubility or insolubility of the polymer (A) in a developer solution, while the compound (Z) serves as a quencher through a superior acid-capturing function being exerted due to the anion in light-unexposed regions, whereby the acid diffused from the light-exposed regions is captured. Accordingly, roughness at an interface between the light-exposed regions and light-unexposed regions is improved, and the difference in solubility into a developer solution between the light-exposed regions and the light-unexposed regions is increased, whereby the resolution can be improved.

The radiation-sensitive composition may contain one type, or two or more types of the compound (Z). The radiation-sensitive composition containing both the compound (Z) that serves as the acid generating agent (B), and the compound (Z) that serves as the acid diffusion control agent (C) together enables a balance among sensitivity, CDU, and development-defect suppressibility to be favorably achieved at a higher level.

In the case in which compound (Z) serves as the acid generating agent (B), the lower limit of a content of the compound (Z) in the radiation-sensitive composition with respect to 100 parts by mass of the polymer (A) is preferably 1 part by mass, and more preferably 5 parts by mass. The upper limit of the content is preferably 20 parts by mass, and more preferably 10 parts by mass.

In the case in which the compound (Z) serves as the acid diffusion control agent (C), the lower limit of a content of the compound (Z) in the radiation-sensitive composition with respect to 100 parts by mass of the polymer (A) is preferably 1 part by mass, and still more preferably 5 parts by mass. The upper limit of the content is preferably 30 parts by mass, and more preferably 20 parts by mass.

The compound (Z) may be a low-molecular-weight compound or may be a polymer. In the case in which the compound (Z) is a polymer, the compound (Z) is a polymer different from the polymer (A). As referred to herein, the “compound” encompasses a “polymer” and a “low-molecular-weight compound”. The “polymer” means a compound having repeating units, and the “low-molecular-weight compound” means a compound that is not a polymer. More specifically, the “low-molecular-weight compound” refers to a compound having a molecular weight of no greater than 2,000.

In the compound (Z), at least one of the anion (X) and the cation (Y) includes an acid-labile group (requirement (iii)). When at least one of the anion (X) and the cation (Y) in the compound (Z) includes an acid-labile group, the solubility in a developer solution is improved, whereby the radiation-sensitive composition may exhibit superior development defect suppressibility.

The acid-labile group is exemplified by those similar to the acid-labile groups described in the section of “Structural Unit (b)” above, and preferred modes thereof are also similar.

The compound (Z) may include the acid-labile group only in the anion (X), may include the acid-labile group only in the cation (Y), or may include the acid-labile group in both the anion (X) and the cation (Y).

It is preferred that at least one of the anion (X) and the cation (Y) in the compound (Z) further includes an iodo group (requirement (iv)). In this case, the sensitivity of the radiation-sensitive composition and CDU can be more improved. Similarly to the case of the requirement (i), in light of enabling the absorption efficiency of radiation to be more improved, the iodo group is preferably bonded to an aromatic ring.

In the case in which requirement (iv) is satisfied in addition to the requirement (iii) above, it is preferred that at least one of the anion (X) and the cation (Y) in the compound (Z) includes both the acid-labile group and the iodo group. In this case, the sensitivity, CDU, and development defect suppressibility of the radiation-sensitive composition can be more improved.

Furthermore, it is preferred that the anion (X) in the compound (Z) includes both the acid-labile group and the iodo group. In this case, the sensitivity, CDU, and development defect suppressibility of the radiation-sensitive composition can be even further improved.

Each structure included in the compound (Z) is described below.

### Anion (X)

The anion (X) has an anion group. The anion group is exemplified by a monovalent organic acid anion group. Examples of the monovalent organic acid anion group include a sulfonic acid anion group (—SO₃⁻), a carboxylic acid anion group (—COO⁻), and a sulfonimidic acid anion group (—SO₂—N⁻—SO₂—). Of these, a sulfonic acid anion group or a carboxylic acid anion group is preferred.

Hereinafter, the anion (X) having a sulfonic acid anion group as the monovalent organic acid anion group is referred to as “anion (X-1)”, and the anion (X) having a carboxylic acid anion group as the monovalent organic acid anion group is referred to as “anion (X-2)”.

### Anion (X-1)

In the case in which the compound (Z) has the anion (X-1), the compound (Z) serves as the radiation-sensitive acid generating agent. In the case in which the compound (Z) serves as the radiation-sensitive acid generating agent, it is preferred that the radiation-sensitive composition further contains the acid diffusion control agent. The acid diffusion control agent is exemplified by the compound (Z) in the case of serving as the acid diffusion control agent, and acid diffusion control agents other than the compound (Z) described later.

In the case in which the compound (Z) has the anion (X-1), the compound (Z) is preferably the low-molecular-weight compound.

The compound (Z) which is the low-molecular-weight compound having the anion (X-1) is not particularly limited as long as the requirement (iii) is satisfied, provided that it is used as a radiation-sensitive acid generating agent in the radiation-sensitive composition.

Among the anions (X-1) in the case in which the compound (Z) is the low-molecular-weight compound, the anion that includes the acid-labile group (in the case in which the requirement (iii) is satisfied) is exemplified by a sulfonic acid anion (hereinafter, may be also referred to as “anion (X-1a)”) represented by the following formula (X-1a).

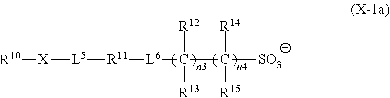

In the above formula (X-1a), R¹⁰ represents an acid-labile group; X represents —COO—* or O—, wherein * denotes a binding site to R¹⁰; L⁵ and L⁶ each independently represent a single bond or a divalent linking group; R¹¹ represents a group obtained by removing two hydrogen atoms from a substituted or unsubstituted ring structure having 5 or more ring atoms; R¹² and R¹³ each independently represent a hydrogen atom, a fluorine atom, an alkyl group having 1 to 10 carbon atoms, or a monovalent fluorinated alkyl group having 1 to 10 carbon atoms; n₃ is an integer of 0 to 10; R¹⁴ and R¹⁵ each independently represent a fluorine atom or a monovalent fluorinated alkyl group having 1 to 10 carbon atoms; and n₄ is an integer of 1 to 10.

The acid-labile group represented by R¹⁰ is exemplified by those similar to the acid-labile groups described in the section of “Structural Unit (b)” above, and preferred modes thereof are also similar.

L⁵, L⁶, R¹¹, R¹², R¹³, R¹⁴, R¹⁵, n₃, and n₄ are exemplified by those similar to L¹, L², R², R³, R⁴, R⁵, R⁶, n₁, and n₂, respectively, in the formula (a) described in the section “Structural Unit (a)” above, and preferred modes thereof are also similar.

Specific examples of the anion (X-1) include sulfonic acid anions represented by the following formulae (X-1-1) to (X-1-8).

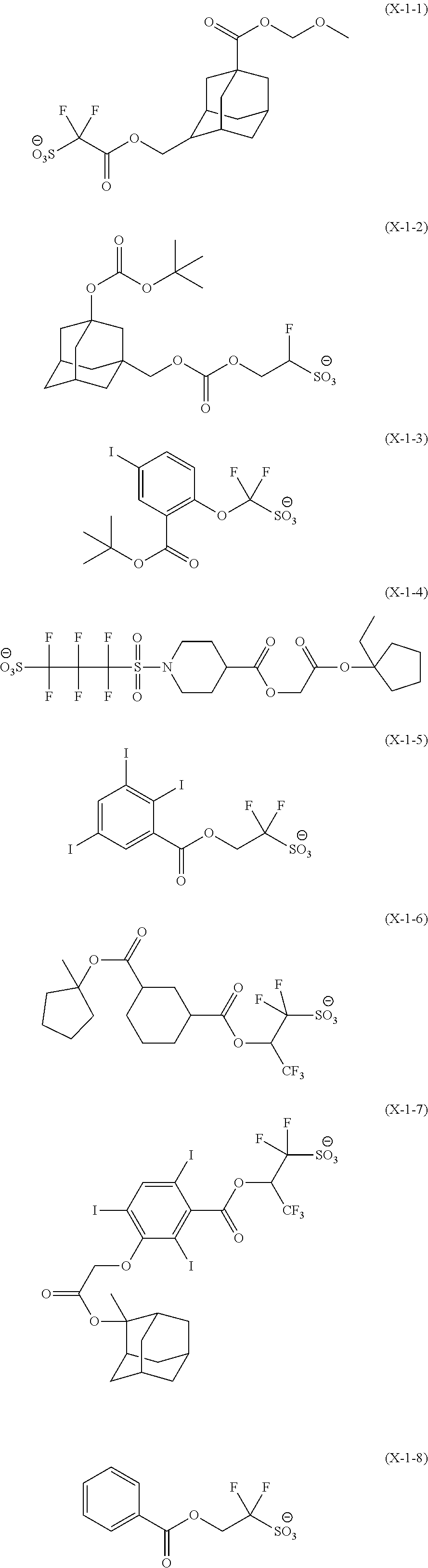

Since the sulfonic acid anions represented by the above formulae (X-1-1) to (X-1-4), (X-1-6), and (X-1-7) each have an acid-labile group, these each correspond to the anion (X-1a) (i.e., satisfying the requirement (iii)). In addition, since the sulfonic acid anions represented by the above formulae (X-1-3), (X-1-5) and (X-1-7) each have an iodo group, the requirement (iv) is satisfied.

### Anion (X-2)

In the case in which the compound (Z) has the anion (X-2), the compound (Z) serves as an acid diffusion control agent. In this case, the radiation-sensitive composition may contain a radiation-sensitive acid generating agent, or may not contain a radiation-sensitive acid generating agent, because the polymer (A) serves as a radiation-sensitive acid-generating polymer. The radiation-sensitive acid generating agent is exemplified by the compound (Z) in the case of serving as the radiation-sensitive acid generating agent, and a radiation-sensitive acid generating agent other than the compound (Z) described later.

In the case in which the compound (Z) has the anion (X-2), the compound (Z) may be a low-molecular-weight compound, or may be a polymer.

The compound (Z) which is the low-molecular-weight compound having the anion (X-2) is not particularly limited as long as the requirement (iii) is satisfied, provided that it is used as a acid diffusion control agent in the radiation-sensitive composition.

Among the anions (X-2) in the case in which the compound (Z) is the low-molecular-weight compound, the anion that includes the acid-labile group (in the case in which the requirement (iii) is satisfied) is exemplified by a sulfonic acid anion (hereinafter, may be also referred to as “anion (X-2b)”) represented by the following formula (X-2b).

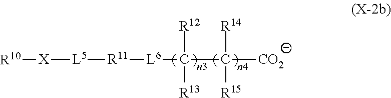

In the above formula (X-2b), R¹⁰, X, L⁵, L⁶, R¹¹, R¹⁴, R¹⁵, n₃, and n₄ are as defined in the above formula (X-1a); R¹⁶ and R¹⁷ each independently represent a hydrogen atom, a fluorine atom, an alkyl group having 1 to 10 carbon atoms, a monovalent fluorinated alkyl group having 1 to 10 carbon atoms, or a group having 1 to 10 carbon atoms that includes an iodo group.

The group having 1 to 10 carbon atoms that includes an iodo group in R¹⁶ and R¹⁷ is exemplified by a group having an aromatic ring that has an iodo group as a substituent.

Specific examples of the anion (X-2) in the case in which the compound (Z) is the low-molecular-weight compound include carboxylic acid anions represented by the following formulae (X-2-1) to (X-2-12).

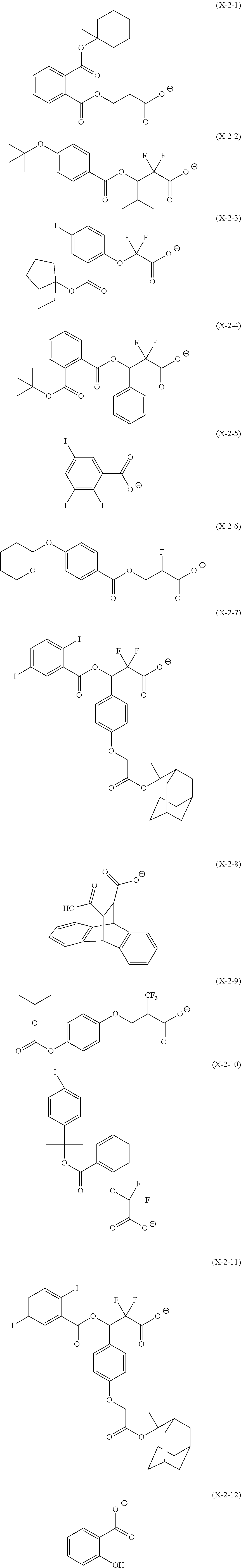

Since the carboxylic acid anions represented by the above formulae (X-2-1) to (X-2-4), (X-2-6), (X-2-7), and (X-2-9) to (X-2-11) each have an acid-labile group, these each correspond to the anion (X-2b) (i.e., satisfying the requirement (iii)). In addition, since the carboxylic acid anions represented by the above formulae (X-2-3), (X-2-5), (X-2-7), (X-2-10), and (X-2-11) each have an iodo group, the requirement (iv) is satisfied.

In the case in which the compound (Z) is a polymer, either a structure (structure (1)) in which the anion (X-2) is bonded to the side chain of the polymer, or a structure (structure (2)) in which the cation (Y) is bonded to the side chain of the polymer is acceptable, and the structure (1) is preferred. The anion (X-2) in the case of the structure (1) is exemplified by one having a structural unit (e) represented by the following formula (X-2c) (the cation being omitted).

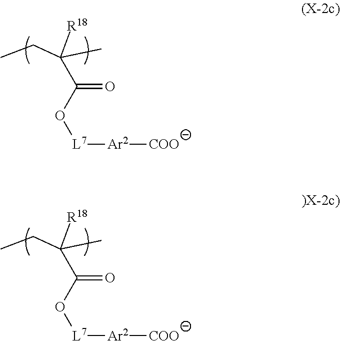

In the above formula (X-2c), R¹⁸ represents a hydrogen atom, a fluorine atom, a methyl group, or a trifluoromethyl group; L⁷ represents a single bond or a divalent linking group; and Ar² represents a group obtained by removing two hydrogen atoms from a substituted or unsubstituted aromatic hydrocarbon ring.

L⁷ represents preferably a divalent linking group.

The aromatic hydrocarbon ring that gives Ar² is exemplified by those exemplified as the aromatic hydrocarbon rings among the ring structures in R² of the above formula (a) described in the section of “Structural Unit (a)” above. The same applies to the substituent. The aromatic hydrocarbon ring that gives Ar¹ is preferably a benzene ring or a naphthalene ring. In the case of having a substituent, a hydroxy group is preferred.

A proportion of the structural unit (e) in the case in which the compound (Z) is a polymer is similar to the proportion of the structural unit (a) in the polymer (A) described above.

In the case in which the compound (Z) is a polymer, the compound (Z) may have other structural unit(s) aside from the structural unit (e). Examples of the other structural unit include the structural unit (b) having an acid-labile group, the structural unit (c) having a phenolic hydroxyl group, the structural unit (d), and the like described in the section of “(A) Polymer” above.

In the case in which the compound (Z) has the structural unit (b) having an acid-labile group as the other structural unit, the compound (Z) satisfies the requirement (iii).

### Cation (Y)

The cation (Y) is a radiation-sensitive onium cation. A valency of the cation (Y) is not particularly limited and may be appropriately predetermined depending on a valency of the anion (X), and the cation (Y) is, for example, monovalent to trivalent, and preferably monovalent.

The cation (Y) is not particularly limited as long as it is known as a radiation-sensitive onium cation in an onium salt to be used in a radiation-sensitive acid generating agent and/or an acid diffusion control agent contained in a radiation-sensitive composition. Cation species in the case of the cation (Y) being the monovalent cation are exemplified by a sulfonium cation (S⁺) and an iodonium cation (I⁺).

In the case in which the cation (Y) is a sulfonium cation, the cation (Y) is exemplified by a monovalent cation represented by the following formula (r-a) described in the section of “Structural Unit (a)” above.

In the case in which the cation (Y) has the acid-labile group, the compound (Z) satisfies the requirement (iii).

Specific examples of the cation (Y) having the acid-labile group include cations represented by the following formulae (Y-1) to (Y-5).

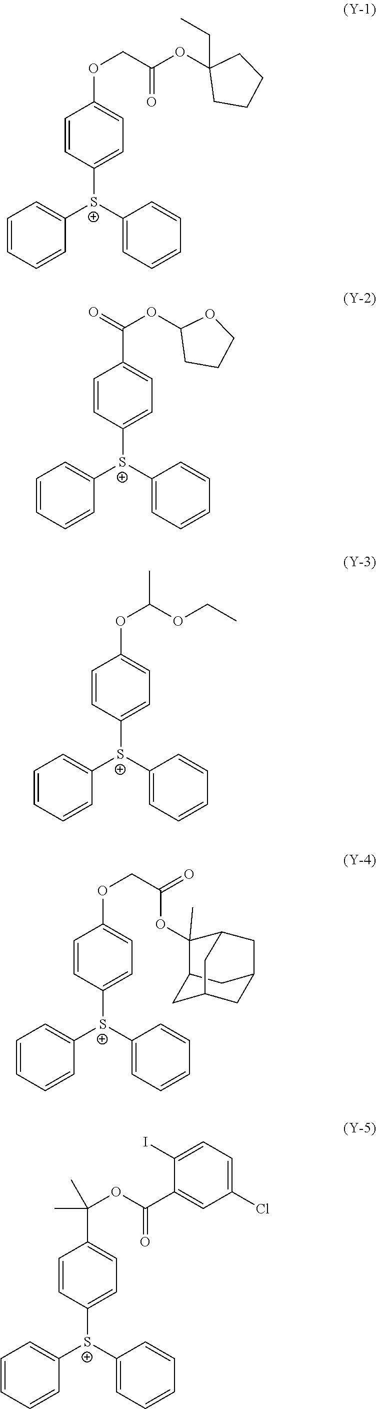 [SMILES: CCC1(OC(=O)COc2ccc([S+](c3ccccc3)c3ccccc3)cc2)CCCC1 ; O=C(OC1CCCO1)c1ccc([S+](c2ccccc2)c2ccccc2)cc1 ; CCOC(C)Oc1ccc([S+](c2ccccc2)c2ccccc2)cc1 ; CC1(OC(=O)COc2ccc([S+](c3ccccc3)c3ccccc3)cc2)C2CC3CC(C2)CC1C3 ; CC(C)(OC(=O)c1cc(Cl)ccc1I)c1ccc([S+](c2ccccc2)c2ccccc2)cc1]

As the compound (Z), a compound obtained by appropriately combining the anion (X) and the cation (Y) can be used as long as the requirement (iii) is satisfied.

### (D) Organic Solvent

The radiation-sensitive composition typically contains the organic solvent (D). The organic solvent (D) is not particularly limited as long as it is a solvent capable of dissolving or dispersing at least the polymer (A) and the compound (Z), as well as the other optional component(s) which may be contained as needed.

The organic solvent (D) is exemplified by an alcohol solvent, an ether solvent, a ketone solvent, an amide solvent, an ester solvent, and a hydrocarbon solvent. The radiation-sensitive composition may contain one type, or two or more types of the organic solvent (D).

Examples of the alcohol solvent include: aliphatic monohydric alcohol solvents such as 4-methyl-2-pentanol, n-hexanol, diacetone alcohol, and 2-hydroxymethyl isobutyrate; alicyclic monohydric alcohol solvents such as cyclohexanol; polyhydric alcohol solvents such as 1,2-propylene glycol; and polyhydric alcohol partial ether solvents such as propylene glycol monomethyl ether.

Examples of the ether solvent include: dialkyl ether solvents such as diethyl ether, dipropyl ether, dibutyl ether, dipentyl ether, diisoamyl ether, dihexyl ether, and diheptyl ether; cyclic ether solvents such as tetrahydrofuran and tetrahydropyran; and aromatic ring-containing ether solvents such as diphenyl ether and anisole.

Examples of the ketone solvent include: chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone, and trimethylnonanone; cyclic ketone solvents such as cyclopentanone, cyclohexanone, cycloheptanone, cyclooctanone, and methylcyclohexanone; and 2,4-pentanedione, acetonylacetone, and acetophenone.

Examples of the amide solvent include: cyclic amide solvents such as N,N′-dimethylimidazolidinone and N-methylpyrrolidone; and chain amide solvents such as N-methylformamide, N,N-dimethylformamide, N,N-diethylformamide, acetamide, N-methylacetamide, N,N-dimethylacetamide, and N-methylpropionamide.

Examples of the ester solvent include: monocarboxylic acid ester solvents such as n-butyl acetate and ethyl lactate; lactone solvents such as γ-butyrolactone and valerolactone; polyhydric alcohol carboxylate solvents such as propylene glycol acetate; polyhydric alcohol partial ether carboxylate solvents such as propylene glycol monomethyl ether acetate; polyhydric carboxylic acid diester solvents such as diethyl oxalate; and carbonate solvents such as dimethyl carbonate and diethyl carbonate.

Examples of the hydrocarbon solvent include: aliphatic hydrocarbon solvents such as n-pentane and n-hexane; and aromatic hydrocarbon solvents such as toluene and xylene.

The organic solvent (D) is preferably the alcohol solvent, the ketone solvent, the ester solvent, or a combination of the same, more preferably the polyhydric alcohol partial ether solvent, the cyclic ketone solvent, the polyhydric alcohol partial ether carboxylate solvent, or a combination of the same, and still more preferably propylene glycol monomethyl ether, cyclohexanone, propylene glycol monomethyl ether acetate, or a combination of the same.

In the case of the radiation-sensitive composition containing the organic solvent (D), the lower limit of a proportion of the organic solvent (D) with respect to total components contained in the radiation-sensitive composition is preferably 50% by mass, more preferably 60% by mass, still more preferably 70% by mass, and particularly preferably 80% by mass. The upper limit of the proportion is preferably 99.9% by mass, more preferably 99.5% by mass, and still more preferably 99.0% by mass.

### (F) Polymer

The polymer (F) is a polymer being different from the polymer (A) and having a percentage content of fluorine atoms greater than that of the polymer (A). In general, a polymer being more hydrophobic than a polymer to serve as the base polymer tends to be localized in a resist film surface layer. Since the polymer (F) has a percentage content of fluorine atoms greater than that of the polymer (A), the polymer (F) tends to be localized in the resist film surface layer due to the characteristic resulting from hydrophobicity. As a result, in the case of the radiation-sensitive composition containing the polymer (F), a cross-sectional shape of a resist pattern to be formed is expected to be favorable. The radiation-sensitive composition may contain the polymer (F) as, for example, a surface-adjusting agent of a resist film. The radiation-sensitive composition may contain one type, or two or more types of the polymer (F).

### Other Optional Component(s)

The other optional component(s) is/are exemplified by an acid generating agent other than the compound (Z), an acid diffusion control agent other than the compound (Z), a surfactant, and the like. The radiation-sensitive composition may contain one type, or two or more types each of the other optional component(s).

The acid generating agent other than the compound (Z) is exemplified by an N-sulfonyloxyimide compound, a sulfonimide compound, a halogen-containing compound, and a diazo ketone compound.

The acid diffusion control agent other than the compound (Z) is exemplified by a nitrogen atom-containing compound. Examples of the nitrogen atom-containing compound include: amine compounds such as tripentylamine and trioctylamine; amide group-containing compounds such as formamide and N,N-dimethylacetamide; urea compounds such as urea and 1,1-dimethylurea; nitrogen-containing heterocyclic compounds such as pyridine, N— (undecylcarbonyloxyethyl) morpholine, N-t-pentyloxycarbonyl-4-hydroxypiperidine; and the like.

### Method of Forming Resist Pattern

The method of forming a resist pattern according to the other embodiment of the present invention includes: a step (hereinafter, may be also referred to as “applying step”) of applying a radiation-sensitive composition directly or indirectly on a substrate; a step (hereinafter, may be also referred to as “exposing step”) of exposing a resist film formed by the applying step; and a step (hereinafter, may be also referred to as “developing step”) of developing the resist film exposed.

In the applying step, the radiation-sensitive composition of the one embodiment of the present invention is used as the radiation-sensitive composition. Therefore, the method of forming a resist pattern enables a resist pattern that is superior in the CDU and development defect suppressibility to be formed with favorable sensitivity.

Each step included in the method of forming a resist pattern will be described below.

### Applying Step

In this step, a radiation-sensitive composition is applied directly or indirectly on the substrate. By this step, the resist pattern is formed directly or indirectly on the substrate.

In this step, the radiation-sensitive composition of the one embodiment of the present invention, described above, is used as the radiation-sensitive composition.

The substrate is exemplified by a silicon wafer and a wafer coated with silicon dioxide or aluminum.

An application procedure is exemplified by spin coating, cast coating, and roll coating. After the application, prebaking (hereinafter, may be also referred to as “PB”) may be carried out as needed for evaporating the solvent remaining in the coating film. A PB temperature and a PB time period are not particularly limited, and for example, PB may be carried out at a temperature of no lower than 60° C. and no higher than 150° C. for a time period of no less than 5 sec and no greater than 300 sec. An average thickness of the resist film to be formed is not particularly limited, and may be, for example, no less than 10 nm and no greater than 1,000 nm.

### Exposing Step

In this step, the resist film formed by the applying step is exposed. This exposure is carried out by irradiation with radiation through a photomask (as the case may be, through a liquid immersion medium such as water). The radiation can be appropriately selected according to a line width, a diameter, and the like of a pattern intended, and examples thereof include electromagnetic waves such as visible light, ultraviolet rays, far ultraviolet rays, extreme ultraviolet rays (EUV), X-rays, and γ-rays; and charged particle rays such as electron beams and a-rays. Of these, far ultraviolet rays, EUV, or electron beams are preferred; an ArF excimer laser beam (wavelength: 193 nm), a KrF excimer laser beam (wavelength: 248 nm), EUV (wavelength: 13.5 nm), or an electron beam is more preferred; a KrF excimer laser beam, EUV, or an electron beam is still more preferred; and EUV or an electron beam is particularly preferred.

It is preferred that post exposure baking (hereinafter, may be also referred to as “PEB”) is carried out after the exposure. This PEB enables an increase in the difference in solubility of the resist film in a developer solution between the light-exposed regions and light-unexposed regions. A PEB temperature and a PEB time period are not particularly limited, and for example, PEB may be carried out at a temperature of no lower than 50° C. and no higher than 180° C. for a time period of no less than 5 sec and no greater than 600 sec.

### Developing Step

In this step, the resist film exposed is developed. Accordingly, formation of a predetermined resist pattern is enabled. The development procedure in the developing step may be carried out by either development with an alkali, or development with an organic solvent.

In the case of the development with an alkali, the developer solution for use in the development is exemplified by: alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (hereinafter, may be also referred to as “TMAH”), pyrrole, piperidine, choline, 1,8-diazabicyclo-[5.4.0]-7-undecene, and 1,5-diazabicyclo-[4.3.0]-5-nonene. Of these, an aqueous TMAH solution is preferred, and a 2.38% by mass aqueous TMAH solution is more preferred.

In the case of the development with an organic solvent, the developer solution is exemplified by the organic solvents exemplified as the organic solvent (D) in the radiation-sensitive composition described above.

### EXAMPLES

Hereinafter, the present invention is explained in detail by way of Examples, but the present invention is not in any way limited to these Examples.

### Synthesis of Polymer

### Synthesis Examples 1 to 18

Polymers (P-1) to (P-16), (Pc-1), and (Pc-2) with formulations shown in Table 1 below were obtained by combining various types of monomers presented below and carrying out a copolymerization reaction in a tetrahydrofuran (THF) solvent, followed by isolation and drying. The formulation of each resulting polymer was confirmed by 1H-NMR, and the Mw and the Mw/Mn were confirmed by GPC as described in the above section “Methods of Measuring Mw and Mn”. The polymers (P-1) to (P-4) and (P-6) to (P-16) correspond to the polymer (A). The polymer (P-5) corresponds to the compound (Z). The polymers (Pc-1) and (Pc-2) are polymers synthesized for control.

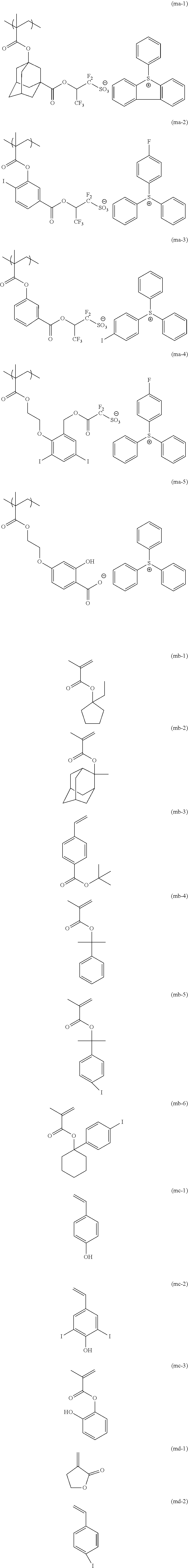

In Table 1 below: “−” denotes that a corresponding structural unit was not contained; “mol %” indicates the proportion of each structural unit with respect to the total structural units constituting the polymer; and “Number of iodo groups” indicates the number of iodo groups in the polymer calculated according to the definition described above.

TABLE 1

| | | Structural | | Structural | | Structural | | Structural | | Number | | |
|---|---|---|---|---|---|---|---|---|---|---|---|---|
| | | unit (a) | | unit (b) | | unit (c) | | unit (d) | | of iodo | | Mw/ |
| | Polymer | type | mol % | type | mol % | type | mol % | type | mol % | groups | Mw | Mn |
| Synthesis | P-1 | ma-1 | 10 | mb-1/ | 15/30 | mc-1 | 40 | md-2 | 5 | 5 | 8,800 | 1.7 |
| Example 1 | | | | mb-4 | | | | | | | | |
| Synthesis | P-2 | ma-2 | 10 | mb-1/ | 15/30 | mc-1 | 40 | md-2 | 5 | 15 | 8,700 | 1.7 |
| Example 2 | | | | mb-4 | | | | | | | | |
| Synthesis | P-3 | ma-3 | 10 | mb-1/ | 15/30 | mc-1 | 40 | md-2 | 5 | 15 | 8,700 | 1.7 |
| Example 3 | | | | mb-4 | | | | | | | | |
| Synthesis | P-4 | ma-4 | 10 | mb-1/ | 15/30 | mc-1 | 40 | md-2 | 5 | 15 | 8,600 | 1.7 |
| Example 4 | | | | mb-4 | | | | | | | | |
| Synthesis | P-5 | ma-5 | 10 | mb-1/ | 15/30 | mc-1 | 40 | md-2 | 5 | 5 | 8,900 | 1.7 |
| Example 5 | | | | mb-4 | | | | | | | | |
| Synthesis | P-6 | ma-1 | 10 | mb-1/ | 15/30 | mc-1 | 40 | md-2 | 5 | 35 | 8,500 | 1.7 |
| Example 6 | | | | mb-5 | | | | | | | | |
| Synthesis | P-7 | ma-1 | 10 | mb-1/ | 15/30 | mc-1 | 40 | md-2 | 5 | 35 | 8,300 | 1.7 |
| Example 7 | | | | mb-6 | | | | | | | | |
| Synthesis | P-8 | ma-1 | 10 | mb-1/ | 15/30 | mc-1/ | 30/10 | md-2 | 5 | 15 | 9,200 | 1.7 |
| Example 8 | | | | mb-4 | | mc-2 | | | | | | |
| Synthesis | P-9 | ma-1 | 10 | mb-1/ | 15/30 | mc-3 | 40 | md-2 | 5 | 5 | 8,500 | 1.7 |
| Example 9 | | | | mb-4 | | | | | | | | |
| Synthesis | P-10 | ma-2 | 10 | mb-1/ | 15/30 | mc-1 | 40 | md-1 | 5 | 10 | 9,100 | 1.7 |
| Example 10 | | | | mb-4 | | | | | | | | |
| Synthesis | P-11 | ma-1 | 10 | mb-1/ | 15/30 | mc-1 | 40 | md-1 | 5 | 30 | 8,900 | 1.7 |
| Example 11 | | | | mb-5 | | | | | | | | |
| Synthesis | P-12 | ma-1 | 10 | mb-1/ | 15/30 | mc-1/ | 30/10 | md-1 | 5 | 10 | 8,900 | 1.7 |
| Example 12 | | | | mb-4 | | mc-2 | | | | | | |
| Synthesis | P-13 | ma-2 | 10 | mb-2/ | 20/30 | mc-1 | 40 | — | — | 40 | 9,600 | 1.7 |
| Example 13 | | | | mb-5 | | | | | | | | |
| Synthesis | P-14 | ma-3 | 10 | mb-1 | 55 | mc-1/ | 25/10 | — | — | 20 | 9,200 | 1.7 |
| Example 14 | | | | | | mc-2 | | | | | | |
| Synthesis | P-15 | ma-1 | 10 | mb-3/ | 10/30 | mc-1/ | 35/15 | — | — | 45 | 9,000 | 1.7 |
| Example 15 | | | | mb-6 | | mc-2 | | | | | | |
| Synthesis | P-16 | ma-2 | 10 | mb-2/ | 20/25 | mc-2/ | 10/30 | md-2 | 5 | 50 | 8,100 | 1.8 |
| Example 16 | | | | mb-6 | | mc-3 | | | | | | |
| Synthesis | Pc-1 | ma-1 | 10 | mb-1/ | 15/30 | mc-1 | 40 | md-1 | 5 | 0 | 9,300 | 1.7 |
| Example 17 | | | | mb-4 | | | | | | | | |
| Synthesis | Pc-2 | — | — | mb-1/ | 15/30 | mc-1 | 40 | md-1/ | 10/5 | 5 | 8,800 | 1.7 |
| Example 18 | | | | mb-4 | | | | md-2 | | | | |

### Preparation of Radiation-Sensitive Composition

The acid generating agent (B), the acid diffusion control agent (C), the organic solvent (D), and the polymer (F) used for preparing the radiation-sensitive composition are shown below. In the following Examples and Comparative Examples, unless otherwise specified particularly, the term “parts by mass” means a value, provided that the mass of the polymer (A) used was 100 parts by mass.

### (B) Acid Generating Agent

Acid generating agents (PAG-1) to (PAG-8), (PAG-A), and (PAG-B) shown below were used as the acid generating agent (B). “Ph₃S⁺” represents a triphenylsulfonium cation. The acid generating agents (PAG-1) to (PAG-8) correspond to the compound (Z) described above.

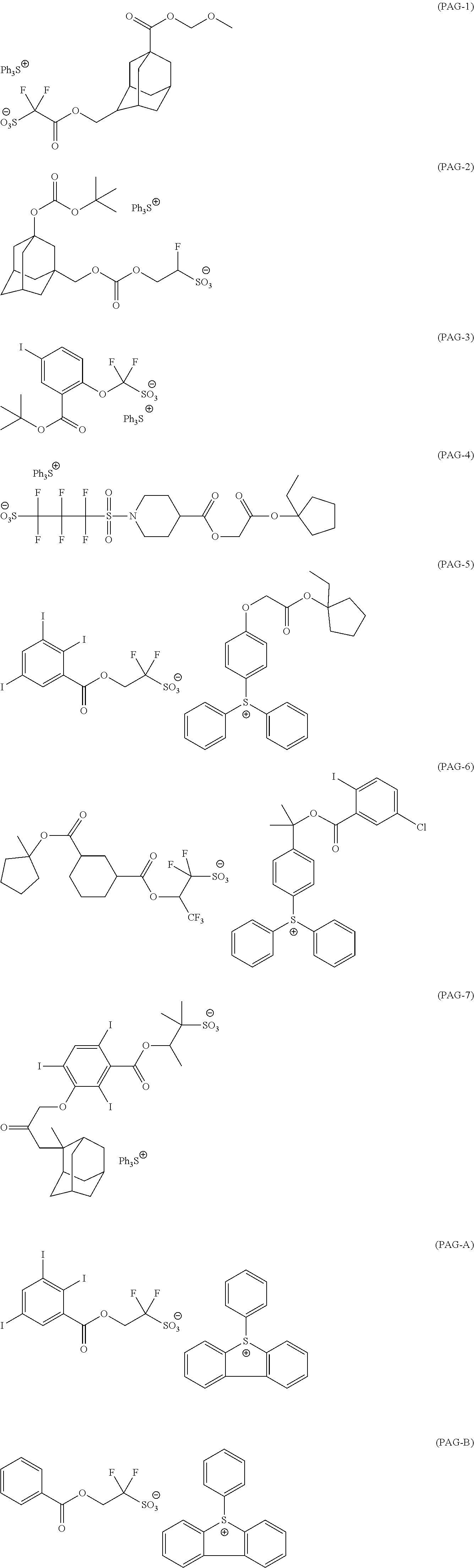

### (C) Acid Diffusion Control Agent

Acid diffusion control agents (Q-1) to (Q-11), (Q-A), and (Q-B) shown below, and the polymer (P-5) synthesized as described above were used as the acid diffusion control agent (C). “Ph₃S⁺” represents a triphenylsulfonium cation. The acid diffusion control agents (Q-1) to (Q-11) and the polymer (P-5) correspond to the compound (Z).

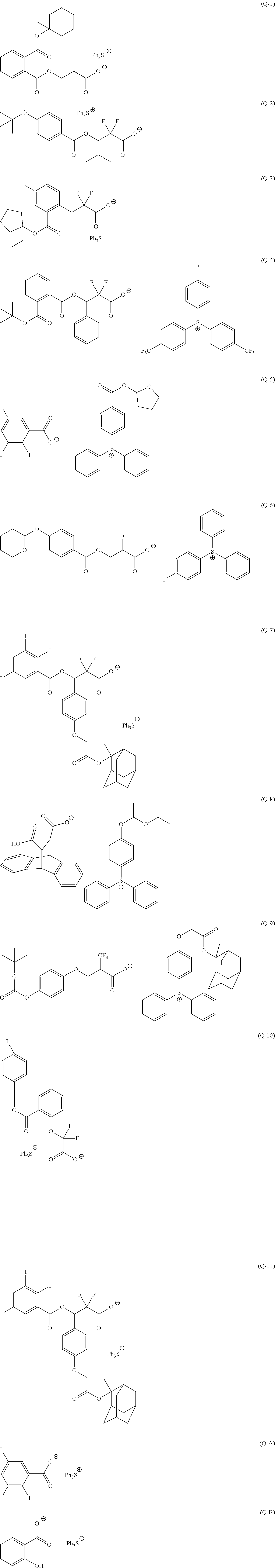

### (D) Organic Solvent

Organic solvents shown below were used as the organic solvent (D).
PGMEA: propylene glycol monomethyl ether acetate
PGME: propylene glycol monomethyl ether
CHN: cyclohexanone

### (F) Polymer

A polymer (F-1) shown below was used as the polymer (F). In the following formula (F-1), the numerical value inscribed at the bottom right of the structural unit indicates the proportion (molar ratio) of the structural unit, with respect to the total structural units constituting the polymer (F). The polymer (F-1) had Mw of 8,900, and Mw/Mn of 2.0.

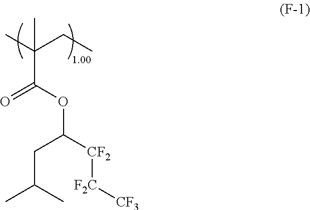

### Examples 1 to 29 and Comparative Examples 1 to 2

Each component with the formulation shown in Table 2 below was dissolved in the organic solvent (D) presented in Table 2 below, in which a surfactant (“FC-4430”, available from 3M Company) had been dissolved at a concentration of 100 ppm. A solution thus obtained was filtered through a nylon filter having a pore size of 0.2 μm to prepare each radiation-sensitive composition.

### Evaluations

Using the radiation-sensitive composition prepared as described above, sensitivity, CDU, and development defect suppressibility were evaluated in accordance with the following methods. The results of the evaluations are shown in Table 2 below.

### Sensitivity

An underlayer antireflective film having an average thickness of 10 nm was formed by applying a composition for underlayer antireflective film formation (“ARC66,” available from Brewer Science, Inc.) on a 12-inch silicon wafer using a spin-coater (“CLEAN TRACK ACT 12,” available from Tokyo Electron Limited), and thereafter heating the composition at 205° C. for 60 sec. Each radiation-sensitive composition prepared as described above was applied on the underlayer antireflective film using the spin-coater, and subjected to PB at 130° C. for 60 sec. Thereafter, by cooling at 23° C. for 30 sec, a resist film having an average thickness of 55 nm was formed. This resist film was exposed with an EUV scanner (“NXE3300”, available from ASML Co.: NA of 0.33, σ 0.9/0.6, quadruple pole illumination, mask of a hole pattern with a dimension on the wafer of pitch: 46 nm, +20% bias). PEB was carried out on a hot plate at 120° C. for 60 sec, and development was performed with a 2.38% by mass aqueous TMAH solution for 30 sec, whereby a resist pattern (23 nm holes, 46 nm pitch) was formed. An exposure dose at which this resist pattern with 23 nm holes and 46 nm pitches was formed was defined as an optimum exposure dose (Eop, unit: mJ/cm²). The Eop being smaller indicates more favorable sensitivity, which was evaluated as: “A” in a case of being less than 13.0 mJ/cm²; “B” in a case of being no less than 13.0 mJ/cm² and less than 14.0 mJ/cm²; “C” in a case of being no less than 14.0 mJ/cm² and less than 15.0 mJ/cm²; “D” in a case of being no less than 15.0 mJ/cm² and less than 16.0 mJ/cm²; or “E” in a case of being no less than 16.0 mJ/cm².

### CDU

A resist pattern (23 nm holes, 46 nm pitch) was formed through irradiation with the Eop exposure dose determined in the above section of Sensitivity, in a similar manner to the above section of Sensitivity. The resist pattern thus formed was observed from above using a scanning electron microscope (“CG-5000”, available from Hitachi High-Technologies Corporation). Hole diameters were measured at 16 sites in an area of 500 nm, and the averaged value was determined. Furthermore, the average value was measured at 500 arbitrary sites in total. A 3 Sigma value was determined from distribution of the measurement values, and thus determined 3 Sigma value was defined as an evaluation value of CDU (units: nm). The CDU with a smaller evaluation value indicates being more favorable, revealing less variance of the hole diameters in greater ranges, which was evaluated as: “A” in a case of being less than 2.20 nm; “B” in a case of being no less than 2.20 nm and less than 2.25 nm; “C” in a case of being no less than 2.25 nm and less than 2.30 nm; “D” in a case of being no less than 2.30 nm and less than 2.35 nm; or “E” in a case of being no less than 2.35 nm.

### Development Defect Suppressibility

An underlayer antireflective film having an average thickness of 10 nm was formed by applying the above-described composition for underlayer antireflective film formation on a 12-inch silicon wafer using the above-described spin-coater, and thereafter heating the composition at 205° C. for 60 sec. Each radiation-sensitive composition prepared as described above was applied on the underlayer antireflective film using the spin-coater, and subjected to PB at 130° C. for 60 sec. Thereafter, by cooling at 23° C. for 30 sec, a resist film having an average thickness of 55 nm was formed. Next, this resist film was exposed with the EUV apparatus (“NXE3300”, available from ASML Co.), using NA=0.33, illumination condition: Conventional s=0.89, mask: imecDEFECT32FFR02. After the exposure, PEB was carried out at 120° C. for 60 sec. Thereafter, using a 2.38% by mass aqueous TMAH solution as an alkaline developer solution, the resist film was subjected to the development with an alkali. After the development, the resist film was washed with water and further dried, whereby a positive-tone resist pattern (32 nm line-and-space pattern) was formed, to be used as a wafer for defect inspection. The number of defects on this wafer for defect inspection was measured by using a defect inspection apparatus (“KLA2810,” available from KLA-Tencor Corporation). The development defect suppressibility was evaluated from the number of defects deemed to be derived from the resist film as: “A” in a case of 10 or fewer; “B” in a case of being 11 to 20; “C” in a case of 21 to 30; “D” in a case of 31 to 50; and “E” in a case of more than 50.

In Table 2 below, “−” denotes that a corresponding component was not contained.

TABLE 2

| | (A) | (B) Acid | (C) Acid | | (F) | | | |
|---|---|---|---|---|---|---|---|---|
| | Polymer | generating | diffusion | (D) Organic | Polymer | | | Development |
| | (parts by | agent (parts | control agent | solvent (parts | (parts by | | | defect |
| | mass) | by mass) | (parts by mass) | by mass) | mass) | Sensitivity | CDU | suppressibility |
| Example 1 | P-1(100) | PAG-1 (5) | Q-A (15) | PGMEA/PGME | F-1 (3) | C | B | D |
| | | | | (1,000/1,500) | | | | |
| Example 2 | P-1(100) | PAG-2 (5) | Q-A (15) | PGMEA/PGME | F-1 (3) | C | B | D |
| | | | | (1,000/1,500) | | | | |
| Example 3 | P-1(100) | PAG-3 (5) | Q-A (15) | PGMEA/PGME | F-1 (3) | B | A | B |
| | | | | (1,000/1,500) | | | | |
| Example 4 | P-1(100) | PAG-4 (5) | Q-A (15) | PGMEA/PGME | F-1 (3) | C | B | D |
| | | | | (1,000/1,500) | | | | |
| Example 5 | P-1(100) | PAG-5 (5) | Q-A (15) | PGMEA/PGME | F-1 (3) | A | A | C |
| | | | | (1,000/1,500) | | | | |
| Example 6 | P-1(100) | PAG-6 (5) | Q-A (15) | PGMEA/PGME | F-1 (3) | B | A | C |
| | | | | (1,000/1,500) | | | | |
| Example 7 | P-1(100) | PAG-7 (5) | Q-A (15) | PGMEA/PGME | F-1 (3) | A | A | B |
| | | | | 1,000/1,500 | | | | |
| Example 8 | P-1(100) | PAG-A (5) | Q-1 (15) | PGMEA/PGME | F-1 (3) | C | B | D |
| | | | | (1,000/1,500) | | | | |
| Example 9 | P-1(100) | PAG-A (5) | Q-2 (15) | PGMEA/PGME | F-1 (3) | C | B | D |
| | | | | (1,000/1,500) | | | | |
| Example 10 | P-1(100) | PAG-A (5) | Q-3 (15) | PGMEA/PGME | F-1 (3) | B | A | B |
| | | | | (1,000/1,500) | | | | |
| Example 11 | P-1(100) | PAG-A (5) | Q-4 (15) | PGMEA/PGME | F-1 (3) | A | B | D |
| | | | | (1,000/1,500) | | | | |
| Example 12 | P-1(100) | PAG-A (5) | Q-5 (15) | PGMEA/PGME | F-1 (3) | A | A | C |
| | | | | (1,000/1,500) | | | | |
| Example 13 | P-1(100) | PAG-A (5) | Q-6 (15) | PGMEA/PGME | F-1 (3) | B | A | C |
| | | | | (1,000/1,500) | | | | |
| Example 14 | P-1(100) | PAG-A (5) | Q-7 (15) | PGMEA/PGME | F-1 (3) | A | A | B |
| | | | | (1,000/1,500) | | | | |
| Example 15 | P-1(100) | PAG-A (5) | Q-8 (15) | PGMEA/PGME | F-1 (3) | C | B | D |
| | | | | (1,000/1,500) | | | | |
| Example 16 | P-1(100) | PAG-A (5) | Q-9 (15) | PGMEA/PGME | F-1 (3) | C | B | D |
| | | | | (1,000/1,500) | | | | |
| Example 17 | P-1(100) | PAG-A (5) | Q-10 (15) | PGMEA/PGME | F-1 (3) | B | A | B |
| | | | | (1,000/1,500) | | | | |
| Example 18 | P-1(100) | PAG-A (5) | Q-11 (15) | PGMEA/PGME | F-1 (3) | A | A | B |
| | | | | (1,000/1,500) | | | | |
| Example 19 | P-2(100) | PAG-1 (5) | Q-A (15) | PGMEA/PGME | F-1 (3) | B | B | D |
| | | | | (1,000/1,500) | | | | |
| Example 20 | P-3(100) | PAG-1 (5) | Q-A (15) | PGMEA/PGME | F-1 (3) | B | B | D |
| | | | | (1,000/1,500) | | | | |
| Example 21 | P-4(100) | PAG-1 (5) | Q-A (15) | PGMEA/PGME | F-1 (3) | B | B | D |
| | | | | (1,000/1,500) | | | | |
| Example 22 | P-6(100) | PAG-1 (5) | Q-A (15) | PGMEA/PGME | F-1 (3) | B | A | D |
| | | | | (1,000/1,500) | | | | |
| Example 23 | P-7(100) | PAG-1 (5) | Q-A (15) | PGMEA/PGME | F-1 (3) | B | A | D |
| | | | | (1,000/1,500) | | | | |
| Example 24 | P-8(100) | PAG-1 (5) | Q-A (15) | PGMEA/PGME | F-1 (3) | B | B | D |
| | | | | (1,000/1,500) | | | | |
| Example 25 | P-9(100) | PAG-1 (5) | Q-A (15) | PGMEA/PGME | F-1 (3) | C | B | D |
| | | | | (1,000/1,500) | | | | |
| Example 26 | P-10(100) | PAG-1 (5) | Q-A (15) | PGMEA/PGME | F-1 (3) | C | B | D |
| | | | | (1,000/1,500) | | | | |
| Example 27 | P-11(100) | PAG-1 (5) | Q-A (15) | PGMEA/PGME | F-1 (3) | B | A | D |
| | | | | (1,000/1,500) | | | | |
| Example 28 | P-12(100) | PAG-1 (5) | Q-A (15) | PGMEA/PGME | F-1 (3) | C | B | D |
| | | | | (1,000/1,500) | | | | |
| Example 29 | P-13(100) | PAG-1 (5) | Q-A (15) | PGMEA/PGME | F-1 (3) | A | A | D |
| | | | | (1,000/1,500) | | | | |
| Example 30 | P-14(100) | PAG-1 (5) | Q-A (15) | PGMEA/PGME | F-1 (3) | B | B | D |
| | | | | (1,000/1,500) | | | | |
| Example 31 | P-15(100) | PAG-1 (5) | Q-A (15) | PGMEA/PGME | F-1 (3) | A | A | D |
| | | | | (1,000/1,500) | | | | |
| Example 32 | P-16(100) | PAG-1 (5) | Q-A (15) | PGMEA/PGME | F-1 (3) | A | A | D |
| | | | | (1,000/1,500) | | | | |
| Example 33 | P-1(100) | — | Q-2 (15) | PGMEA/PGME | F-1 (3) | D | C | A |
| | | | | (1,000/1,500) | | | | |
| Example 34 | P-1(100) | — | Q-3 (15) | PGMEA/PGME | F-1 (3) | C | B | A |
| | | | | (1,000/1,500) | | | | |
| Example 35 | P-1(100) | — | Q-11 (15) | PGMEA/PGME | F-1 (3) | C | B | A |
| | | | | (1,000/1,500) | | | | |
| Example 36 | P-1(100) | PAG-3 (5) | Q-11 (15) | PGMEA/PGME | F-1 (3) | B | A | A |
| | | | | (1,000/1,500) | | | | |
| Example 37 | P-1(100) | PAG-7 (5) | Q-11 (15) | PGMEA/PGME | F-1 (3) | A | A | A |
| | | | | (1,000/1,500) | | | | |
| Example 38 | P-2(100) | — | Q-11 (15) | PGMEA/PGME | F-1 (3) | B | B | A |
| | | | | (1,000/1,500) | | | | |
| Example 39 | P-6(100) | — | Q-11 (15) | PGMEA/PGME | F-1 (3) | B | A | A |
| | | | | (1,000/1,500) | | | | |
| Example 40 | P-13(100) | — | Q-11 (15) | PGMEA/PGME | F-1 (3) | A | A | A |
| | | | | (1,000/1,500) | | | | |
| Example 41 | P-1(100) | — | P-5 (10) | PGMEA/PGME | F-1 (3) | C | D | A |
| | | | | (1,000/1,500) | | | | |
| Example 42 | P-4(100) | — | Q-1/Q-A | PGMEA/CHN | — | B | B | D |
| | | | (7.5/7.5) | (2,000/500) | | | | |
| Comparative | P-1(100) | PAG-A (5) | Q-A (15) | PGMEA/PGME | F-1 (3) | A | A | E |
| Example 1 | | | | (1,000/1,500) | | | | |
| Comparative | P-1(100) | PAG-B (5) | Q-B (15) | PGMEA/PGME | F-1 (3) | E | E | A |
| Example 2 | | | | (1,000/1,500) | | | | |
| Comparative | Pc-1(100) | PAG-1 (5) | Q-A (15) | PGMEA/PGME | F-1 (3) | E | C | D |
| Example 3 | | | | (1,000/1,500) | | | | |
| Comparative | Pc-2(100) | PAG-1 (5) | Q-A (15) | PGMEA/PGME | F-1 (3) | C | E | D |
| Example 4 | | | | (1,000/1,500) | | | | |

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A radiation-sensitive composition comprising:
a polymer, solubility of which in a developer solution is capable of being altered by an action of an acid; and
a compound comprising an anion and a radiation-sensitive onium cation, wherein
the polymer has a structural unit comprising a group that generates a sulfonic acid by an action of radiation,
the polymer comprises an iodo group, and
at least one of the anion and the radiation-sensitive onium cation comprises an acid-labile group.

2. The radiation-sensitive composition according to claim 1, wherein at least one of the anion and the radiation-sensitive onium cation further comprises an iodo group.

3. The radiation-sensitive composition according to claim 2, wherein at least one of the anion and the radiation-sensitive onium cation comprises both the acid-labile group and the iodo group.

4. The radiation-sensitive composition according to claim 3, wherein the anion comprises both the acid-labile group and the iodo group.

5. A method of forming a resist pattern, the method comprising:
applying the radiation-sensitive composition according to claim 1 directly or indirectly on a substrate to form a resist film;
exposing the resist film formed; and
developing the resist film exposed.
